(19) United States
(12) Patent Application Publication
(10) Pub. No.: US 2017/0330773 A1
(43) Pub. Date: Nov. 16, 2017

(54) PLASMA PROCESSING SYSTEM USING ELECTRON BEAM AND CAPACITIVELY-COUPLED PLASMA

(71) Applicant: KOREA ADVANCED INSTITUTE OF SCIENCE AND TECHNOLOGY, Daejeon (KR)

(72) Inventors: Hong-Young Chang, Daejeon (KR); Inshik Bae, Daejeon (KR); Gi-Jung Park, Daejeon (KR)

(21) Appl. No.: 15/590,714

(22) Filed: May 9, 2017

(30) Foreign Application Priority Data
May 10, 2016 (KR) 10-2016-0056764

(51) Int. Cl. H01L 21/67; H01L 21/02; H01L 21/687; H01L 21/3065; H05H 15/00; H05H 1/46

(52) U.S. Cl. CPC H01L 21/67063; H01L 21/3065; H05H 15/00; H01L 21/02032; H01L 21/687; H05H 2001/4675; H01L 2221/683

(57) ABSTRACT

A plasma processing system. The system may include a vacuum chamber including an electron emission region and a processing region, in which plasma is produced and a substrate is loaded, the electron emission region having a first pressure and the processing region being maintained to a pressure higher than the first pressure, a thermal electron emission unit provided in the electron emission region and used to emit a thermal electron, a grid electrode grounded and used to selectively provide an electron emitted from the thermal electron emission unit to the processing region, a substrate holder provided in a lower region of the vacuum chamber and in the processing region, the substrate holder being used to load the substrate thereon, and an RF power source configured to apply an RF power to the substrate holder and to produce the plasma.

### CROSS-REFERENCE TO RELATED APPLICATION

This U.S. non-provisional patent application claims priority under 35 U.S.C. §119 to Korean Patent Application No. 10-2016-0056764, filed on May 10, 2016, in the Korean Intellectual Property Office, the entire contents of which are incorporated by reference herein.

### BACKGROUND

The present disclosure relates to a plasma processing system, and in particular, to a plasma processing system with an electron beam source and a capacitively-coupled plasma unit.

Plasma is used to perform an etch, deposition, or surface-treatment process on a substrate. For example, in an etching process for forming fine patterns, it is necessary to use plasma under an extremely low pressure of several mTorr or lower. For this, plasma is produced using a high density plasma source, and then, a neutral beam is formed by selectively extracting ions from the plasma. The neutral beam is used in an etching process for forming fine patterns.

However, in general, a neutral-beam etching system has a complex structure and a difficulty in producing a sufficient amount of neutral beam.

Thus, it is necessary to develop a novel plasma processing system, which can be used in an etching process for forming fine patterns of high aspect ratio.

### SUMMARY

Some embodiments of the inventive concept provide a plasma processing system, which is configured to produce capacitively-coupled plasma using an electron beam within a pressure range capable of preventing capacitively-coupled plasma from being produced. Due to the electron beam and the plasma, it may be possible to realize a high RF bias voltage and to increase the straightness of ions.

According to some embodiments of the inventive concept, a plasma processing system may include a vacuum chamber including an electron emission region and a processing region, in which plasma is produced and a substrate is loaded, the electron emission region having a first pressure and the processing region being maintained to a pressure higher than the first pressure, a thermal electron emission unit provided in the electron emission region and used to emit a thermal electron, a grid electrode grounded and used to selectively provide an electron emitted from the thermal electron emission unit to the processing region, a substrate holder provided in a lower region of the vacuum chamber and in the processing region, the substrate holder being used to load the substrate thereon, an RF power source configured to apply an RF power to the substrate holder and to produce the plasma, a first vacuum pump connected to the electron emission region, and a second vacuum pump connected to the processing region.

In some embodiments, the electron emission unit may include a graphite heating part having a winding structure, an electron emission part provided below the graphite heating part, the electron emission part being in thermal contact with the graphite heating part and being used to emit thermal electrons, a graphite cover part provided to surround the electron emission part and graphite heating part, the graphite cover part including an opening exposing a bottom surface of the electron emission part, and a spacer provided between a top surface of the graphite cover part and the graphite heating part.

In some embodiments, the electron emission part may be formed of LaB₆ or CeB₆.

In some embodiments, the plasma processing system may further include a DC heating power source connected to opposite ends of the graphite heating part and used to supply a DC current to the graphite heating part, and an energy control power source connected to the graphite cover part and used to control a potential energy of an emitted electron.

In some embodiments, the plasma processing system may further include a process gas supplying part configured to supply a process gas to the processing region, and a reclaiming gas supplying part configured to supply a reclaiming gas to an exposed portion of the electron emission part, when the exposed portion of the electron emission part is reacted with the process gas and has a changed property.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a diagram schematically illustrating a plasma processing system according to some embodiments of the inventive concept.

FIG. 2 is a perspective view illustrating a thermal electron generation unit of FIG. 1.

FIG. 3 is a perspective view illustrating a grid electrode of FIG. 1.

FIG. 4 illustrates a change in voltage of a substrate holder caused by the presence of an electron beam.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

To produce capacitively-coupled plasma, it may be necessary to apply an RF power to an electrode at pressure of several tens mTorr or higher. However, in the case that the plasma is produced at such a high pressure, it is difficult to etch fine patterns, due to low ion energy and collisions of neutral particles. Thus, many studies have been conducted to reduce a frequency of an RF power and thereby to increase the RF bias. However, in the case that the frequency of the RF power is reduced, a plasma density is reduced. Accordingly, there is a demand for a novel plasma processing technology, allowing for high ion energy even at low pressure.

In an RF capacitively-coupled plasma at pressure of several tens mTorr (preferably, 10 mTorr or lower), ions may be incident into a substrate with a bias voltage. In general, the bias voltage may be determined by characteristics of ions and electrons. In the case that an RF power is supplied to a substrate holder, on which the substrate is loaded, via a blocking capacitor, the substrate holder may be configured to have a bias voltage.

According to some embodiments of the inventive concept, in order to increase a bias voltage of an RF capacitively-coupled plasma, an electron beam may be supplied from the outside. The electron beam may be supplied to move toward the substrate without any collision to neutral gas and may be used to neutralize charging caused by ions. In addition, an electron beam producing unit, which is used to produce the electron beam, may include an electron emission part that is formed of or includes lanthanum hexaboride (LaB₆) or cerium hexaboride (CeB₆). The electron emission part may be heated by a graphite heating part and may have an electric potential that can be controlled in an independent manner. Accordingly, the emitted thermal electrons may be used as an electron beam that propagates toward a grid electrode and has a desired energy.

Example embodiments of the inventive concept will now be described more fully with reference to the accompanying drawings, in which example embodiments are shown. Example embodiments of the inventive concept may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concept belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

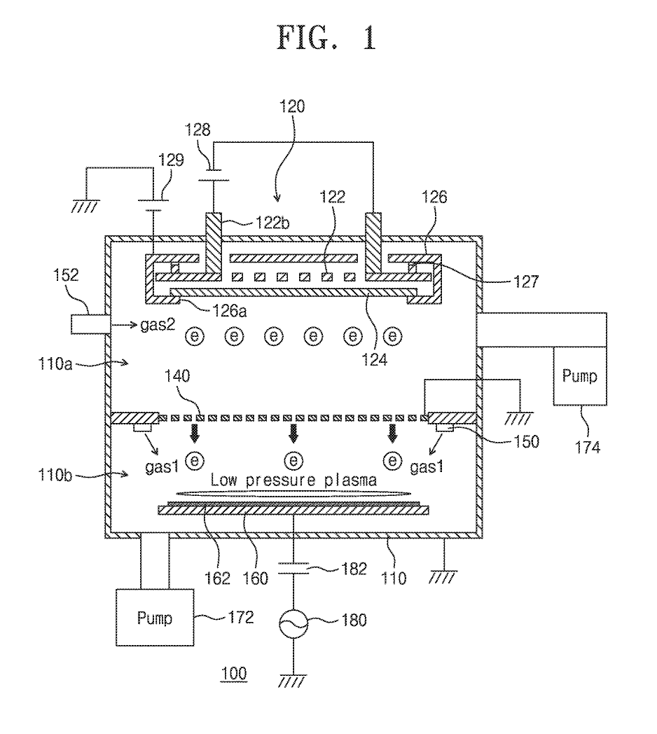

FIG. 1 is a diagram schematically illustrating a plasma processing system according to some embodiments of the inventive concept.

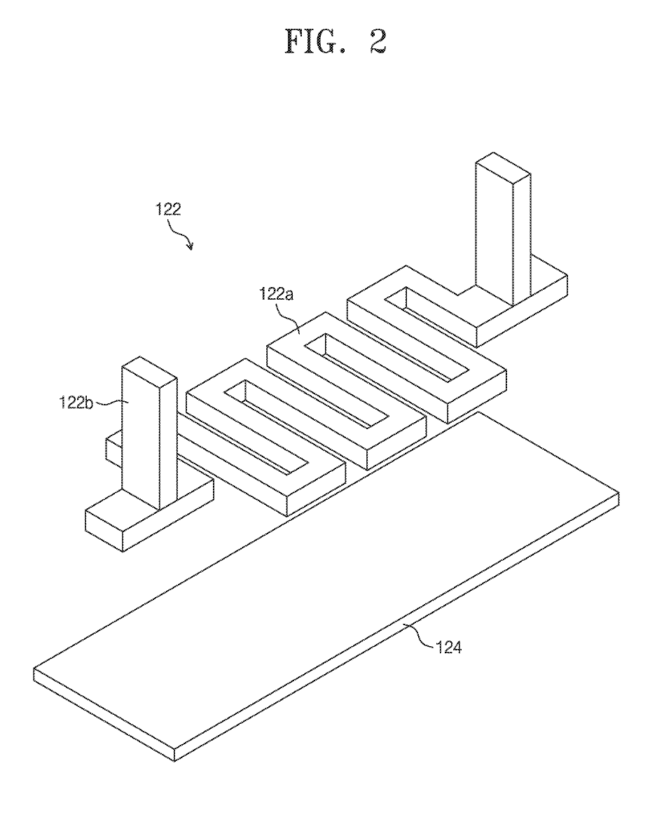

FIG. 2 is a perspective view illustrating a thermal electron generation unit of FIG. 1.

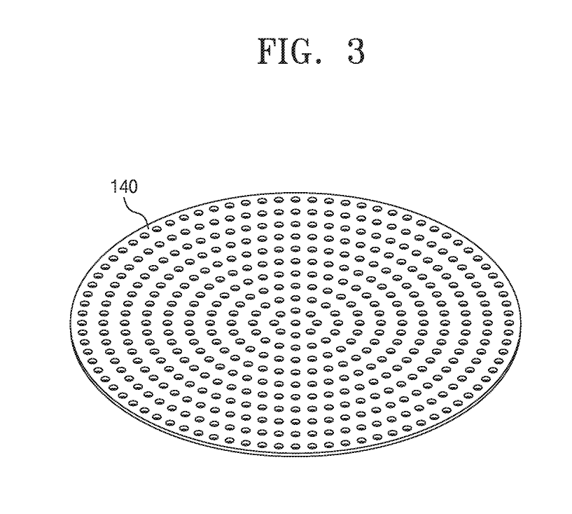

FIG. 3 is a perspective view illustrating a grid electrode of FIG. 1.

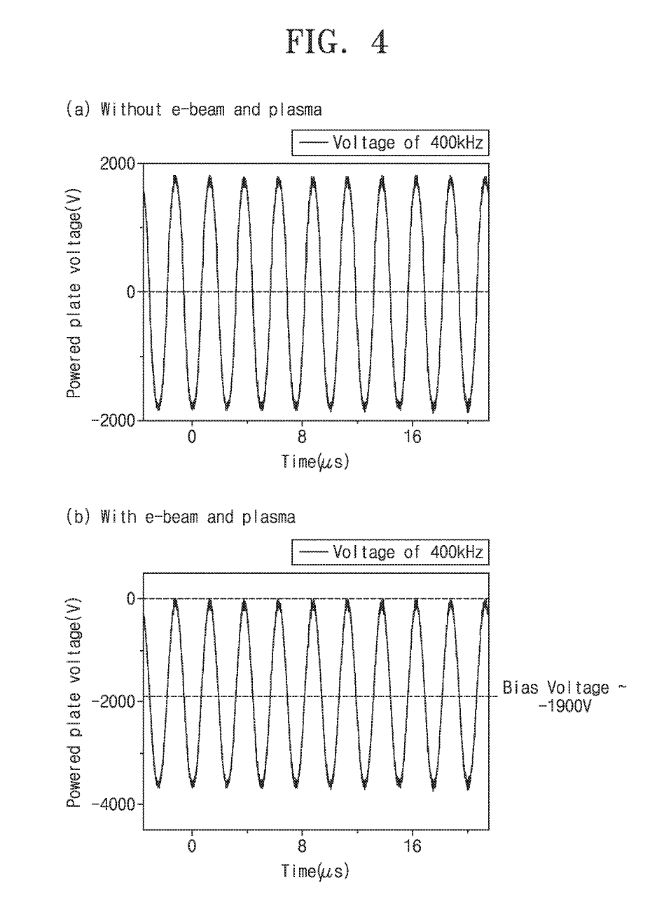

FIG. 4 illustrate a change in voltage of a substrate holder caused by the presence of an electron beam.

Referring to FIGS. 1 and 2, a plasma processing system 100 may include a vacuum chamber 110, a thermal electron emission unit 120, a grid electrode 140, a substrate holder 160, an RF power source 180, a first vacuum pump 174, and a second vacuum pump 172. The vacuum chamber 110 may include an electron emission region 110a, which is maintained to a first pressure, and a processing region 110b, which is maintained to a pressure higher than the first pressure and is used to produce plasma and dispose a substrate therein. The thermal electron emission unit 120 may be provided in the electron emission region 110a and may be used to emit thermal electrons. The grid electrode 140 may be grounded and may be used to provide the electrons, which are emitted from the thermal electron emission unit 120, to the processing region 110b. The substrate holder 160 may be provided in a lower region (e.g., the processing region 110b) of the vacuum chamber 110 and may be used to load the substrate thereon. The RF power source 180 may be configured to supply RF power, which is used to produce the plasma, to the substrate holder 160. The first vacuum pump 174 may be connected to the electron emission region 110a, and the second vacuum pump 172 may be connected to the processing region 110b.

The vacuum chamber 110 may be a cylindrical metal chamber or a rectangular parallelepiped metal chamber. The vacuum chamber 110 may be provided to include the electron emission region 110a and the processing region 110b. The electron emission region and the processing region 110b may be separated based on the position of the grid electrode 140. The electron emission region 110a may be configured to have a first pressure, and the processing region 110b may be configured to have a second pressure higher than the first pressure. To realize a non-vanishing pressure gradient, the first vacuum pump 174 may be connected to the electron emission region 110a, and the second vacuum pump 172 may be connected to the processing region 110b.

The thermal electron emission unit 120 may be provided in the electron emission region 110a or in an upper region of the vacuum chamber 110. The thermal electron emission unit 120 may be configured to emit thermal electrons, and such thermal electrons may be accelerated by the grounded grid electrode 140 to form an electron beam. In the processing region 110b, the electron beam may provide functions for initial discharging or sustaining, and this may be used to easily form a RF capacitively-coupled plasma.

In the case where the electron beam is not incident into the processing region 110b, at the second pressure, there may be a difficulty in producing capacitively-coupled plasma using the substrate holder (e.g., an electrode for capacitively-coupled plasma). By contrast, in the case where the electron beam is incident into the processing region 110b, at the second pressure, the substrate holder 160 may be used to produce capacitively-coupled plasma.

The grid electrode 140 may be a porous plate or a mesh structure. For example, the grid electrode 140 may include a conductive plate, in which holes arranged in a matrix shape are formed. The grid electrode 140 may be configured to realize a non-vanishing pressure gradient between the processing region 110b and the electron emission region 110a, and thus, it may be used to selectively provide an incident electron beam to the processing region 110b. The hole may have a diameter ranging from 0.5 mm to 10 mm A distance between the holes may be less than 10 mm A thickness of the grid electrode 140 may be of the order of several millimeters.

The grid electrode 140 may be provided in such a way that a ratio in area of an open region to a closed region ranges from 1% to 90%. Because of the grid electrode 140, pressure of the processing region 110b may range from 0.5 mTorr to 10 mTorr. Pressure of the electron emission region 110a may be equal to or lower than 0.5 mTorr.

The electron emission unit 120 may include a graphite heating part 122, an electron emission part 124, a graphite cover part 126 with an opening 126a, and a spacer 127. The graphite heating part 122 may be provided to have a winding structure. The electron emission part 124 may be provided below the graphite heating part 122 to be in thermal contact with the graphite heating part 122 and may be used to emit thermal electrons. The opening 126a may be provided to expose a bottom surface of the electron emission part 124. The graphite cover part 126 may be provided to enclose the electron emission part 124 and the graphite heating part 122. The spacer 127 may be provided between a top surface of the graphite cover part 126 and the graphite heating part 122.

The graphite heating part 122 may include a heating portion 122a, which is provided to have a winding structure, and power supply rods 122b, which are respectively connected to opposite ends of the heating portion 122a. In some embodiments, the heating portion 122a and the power supply rod 122b may be formed of graphite. The power supply rod 122b may be connected to a DC heating power source 128 via a port, which is formed through the top surface of the vacuum chamber 110. The DC heating power source 128 may be connected to the power supply rod 122b and may be used to supply a DC current through the power supply rod 122b and to heat the heating portion 122a up to temperature of 1000° C. or higher. The graphite heating part 122 may be provided to have low thermal conductivity and this may make it possible to prevent or suppress heat energy from being leaked to the outside. The DC heating power source 128 may be configured to supply an electric current of several amperes to several hundred amperes. A thickness of the heating portion 122a may range from several millimeters to several centimeters. The heating portion 122a may be provided to have a winding shape and this may make it possible to uniformly heat one of surfaces of the electron emission part 124.

The electron emission part 124 may be a plate-shaped structure and may be provided to be in contact with the bottom surface of the heating portion 122a. The electron emission part 124 may be uniformly heated to temperature ranging from 1000° C. to 1800° C. by the graphite heating part 122 and thus it may be used to emit thermal electrons. The electron emission part 124 may be formed of or include LaB₆ or CeB₆.

The graphite cover part 126 may be provided to surround the electron emission part 124 and the graphite heating part 122. The opening 126a, which allows electrons emitted from the electron emission part 124 to pass therethrough, may be formed through a bottom surface of the graphite cover part 126. The opening 126a may be aligned to an edge region of the electron emission part 124, and this alignment of the opening 126a may allow an electron beam to be aligned to the grid electrode 140. The graphite cover part 126 may be or include plates, each of which has a size of several millimeters to several centimeters.

The spacer 127 may be provided between a top surface of the graphite cover part 126 and the graphite heating part 122 to electrically separate them from each other. The spacer 127 may be a disk-shaped structure having a height of several millimeters. The spacer 127 may include a high resistance portion and a graphite portion which are stacked. The high resistance portion may be formed of tantalum. The high resistance portion may be formed of a material having high electric resistance and high melting point. The high resistance portion may prevent an electric current from flowing toward the graphite cover part 126. In addition, the spacer 127 may prevent the graphite cover part 126 and the graphite heating part 122 from being in direct contact with each other.

An energy control power source 129 may be connected to the graphite cover part 126 and may be used to control a potential energy of an emitted electron. The graphite cover part 126 may be maintained to have a negative voltage. The graphite cover part 126 may be provided to support a lower edge portion of the electron emission part 124 and may be electrically connected to the electron emission part 124.

For example, the negative voltage may range from several ten volts to several hundred volts. Accordingly, the thermal electrons may be accelerated toward the grid electrode 140. The energy of the electron beam may be controlled by adjusting the applied voltage.

The energy control power source 129 may be used to accelerate the electron beam. Here, due to the mutual interaction between electrons, the electron beam may have the Maxwell distribution, and in certain embodiments, the Maxwell distribution may have a full width half maximum (FWHM) ranging from several volts to several ten volts.

A process gas supplying part 150 may be configured to supply a process gas to the processing region 110b. In the case of an etching process, the process gas may be a fluorine-containing gas or a chlorine-containing gas. The process gas supplying part 150 may be configured to uniformly spray the process gas onto the substrate (e.g., using a ring-shaped process gas distribution unit). A grid electrode holder may be provided to support the grid electrode 140, and the process gas supplying part 150 may be a ring-shaped structure that is disposed along a bottom surface of the grid electrode holder.

Physical and chemical characteristics of an exposed portion of the electron emission part 124 may be changed by the process gas. In some embodiments, a reclaiming gas supplying part 152 may be provided to supply a reclaiming gas for reclaiming the exposed portion of the electron emission part 124 into the electron emission region 110a. The reclaiming gas may be an oxygen gas. In the case where, owing to the use of fluorine, the chemical structure of the electron emission part 124 is changed to LaF₃ or CeF₃, the oxygen gas may combine with fluorine atoms of LaF₃ or CeF₃, thereby cleaning or reclaiming a surface of the electron emission part 124.

The substrate holder 160 may be configured to load a substrate 162 thereon and may be used as an electrode for producing the capacitively-coupled plasma. The substrate holder 160 may be connected to the RF power source 180 through the blocking capacitor 182. The blocking capacitor 182 may be used to maintain an RF bias voltage to a desired level.

The frequency of the RF power source 180 may range from several hundred kHz to several ten MHz. Preferably, the frequency of the RF power source 180 may range from 300 kHz to 1 MHz. If an electron beam is used to produce the capacitively-coupled plasma, it is difficult to produce the capacitively-coupled plasma at the low frequency of 300 kHz to 1 MHz and the low pressure of 10 mTorr or lower. By contrast, according to some embodiments of the inventive concept, the electron beam may be used to produce the capacitively-coupled plasma, and in this case, it may be possible to produce a capacitively-coupled plasma having a bias voltage of several thousand volts or higher, at the low frequency of 300 kHz to 1 MHz and the low pressure of 10 mTorr or lower. The RF bias voltage may be maintained to a level of 2000V or higher. Thus, it may be possible to perform an etching process on a fine pattern, to which the conventional etching process cannot be applied.

The first vacuum pump 174 may be connected to the electron emission region 110a and may be configured to allow the electron emission region 110a to have a pressure lower than the processing region 110b. The second vacuum pump 172 may be connected to the processing region 110b and may be used to exhaust by-products, which is produced by the plasma, to the outside.

Referring to FIG. 4, when an electron beam was not provided, the pressure of the processing region 110b was about 1 mTorr and the pressure of the electron emission region 110a was lower than or equal to 1 mTorr. In this case, plasma was not produced, and thus, the waveform was symmetrical about the line of 0V.

When the electron beam was provided, an RF power of 400 kHz was applied to the substrate holder serving as an electrode. In this case, the pressure of the processing region 110b was about 1 mTorr and the pressure of the electron emission region 110a was lower than or equal to 1 mTorr. The RF bias voltage was about −1900V. The voltage was substantially non-positive. However, since electrons due to an electron beam were provided to a substrate, the substrate, which was charged by positive ions, was neutralized. Thus, a high bias voltage was produced.

In an RF capacitively-coupled plasma processing system using an electron beam, since plasma has low density or high resistance, a voltage to be applied under the same RF power may be high, and thus, it may be possible to produce a high bias voltage and to increase an ion energy. Accordingly, an etching process may be performed to form a pattern having a high aspect ratio.

In addition, since the processing region 110b has low pressure, the electron beam may reach the substrate 162 without collision in the processing region 110b. The electron beam may reach a bottom surface of an etching pattern having a high aspect ratio, and thus, it may be possible to overcome a charging issue caused by ions.

The energy of the electron beam may be adjusted to realize selective dissociation of a process gas. In some embodiments, by controlling a voltage between the grid electrode and the energy control power source, it may be possible to control the energy of the electron beam. An RF capacitively-coupled plasma provided with the electron beam may have a significantly increased RF bias voltage, compared to the case in which there is no electron beam. Thus, according to some embodiments of the inventive concept, it may be possible to significantly increase the ion energy and to perform an etching process on a fine pattern having a high aspect ratio.

According to some embodiments of the inventive concept, a stable electron beam is provided to a plasma processing system. This makes it possible for the plasma processing system to produce capacitively-coupled plasma at pressure of 10 mTorr or lower and to etch a pattern having a high aspect ratio.

While example embodiments of the inventive concept have been particularly shown and described, it will be understood by one of ordinary skill in the art that variations in form and detail may be made therein without departing from the spirit and scope of the attached claims.

What is claimed is:

1. A plasma processing system, comprising:
a vacuum chamber including an electron emission region and a processing region, for producing plasma and in which a substrate is loaded, the electron emission region having a first pressure and the processing region being maintained to a pressure higher than the first pressure;
a thermal electron emission unit in the electron emission region and for emitting a thermal electron;
a grid electrode grounded and for selectively providing an electron emitted from the thermal electron emission unit to the processing region;
a substrate holder provided in a lower region of the vacuum chamber and in the processing region, the substrate holder configured for to be used to load the substrate thereon;
an RF power source configured to apply an RF power to the substrate holder and to produce the plasma;
a first vacuum pump connected to the electron emission region; and
a second vacuum pump connected to the processing region.

2. The plasma processing system of claim 1, wherein the electron emission unit comprises:
a graphite heating part having a winding structure;
an electron emission part provided below the graphite heating part, the electron emission part being in thermal contact with the graphite heating part and configured for use to emit thermal electrons;
a graphite cover part to surround the electron emission part and graphite heating part, the graphite cover part including an opening exposing a bottom surface of the electron emission part; and
a spacer provided between a top surface of the graphite cover part and the graphite heating part.

3. The plasma processing system of claim 2, wherein the electron emission part is formed of LaB₆ or CeB₆.

4. The plasma processing system of claim 2, further comprising:
a DC heating power source connected to opposite ends of the graphite heating part to supply a DC current to the graphite heating part; and
an energy control power source connected to the graphite cover part to control a potential energy of an emitted electron.

5. The plasma processing system of claim 3, further comprising:
a process gas supplying part configured to supply a process gas to the processing region; and
a reclaiming gas supplying part configured to supply a reclaiming gas to an exposed portion of the electron emission part, when the exposed portion of the electron emission part is reacted with the process gas and has a changed property.
